(19) United States
(12) Patent Application Publication
(10) Pub. No.: US 2021/0287984 A1
(43) Pub. Date: Sep. 16, 2021

(54) ON INTEGRATED CIRCUIT (IC) DEVICE CAPACITOR BETWEEN METAL LINES

(71) Applicant: International Business Machines Corporation, Armonk, NY (US)

(72) Inventors: Baozhen Li, South Burlington, VT (US); Jim Shih-Chun Liang, Poughkeepsie, NY (US); Chih-Chao Yang, Glenmont, NY (US); Huimei Zhou, Albany, NY (US)

(21) Appl. No.: 16/819,291

(22) Filed: Mar. 16, 2020

(51) Int. Cl. H01L 23/522; H01L 21/768; H01L 49/02

(52) U.S. Cl. CPC H01L 23/5223; H01L 28/87; H01L 21/768

(57) ABSTRACT

An IC device includes capacitor elements formed within the same wiring level and in an area of the wiring level that is between a pair of wiring lines. This area may be an area that is not previously utilized, may be an area where dummy metal features were traditionally utilized, or the like. In a first implementation, the capacitor elements include a first capacitor comb interleaved with a second capacitor comb. In another implementation, the capacitor element is a perforated capacitor plate. The geometry of the interleaved capacitor combs and the open area of the perforations may be tuned in order to achieve or meet a predetermined uniform wiring level metal density requirement(s). The IC device may utilize a capacitor formed at least in part with the capacitor elements as a decoupling capacitor, a noise filter, a sensor, or the like.

### FIELD

Embodiments of invention generally relate to integrated circuit (IC) devices and IC device fabrication methods. More particularly, embodiments relate to IC devices with a capacitor between metal lines.

### BACKGROUND

The high frequency and low power that which modern IC devices operate may require utilization of decoupling capacitors within the IC device. MIMcap solutions, one such example is described in U.S. Pat. No. 9,627,312, have been utilized within IC devices for decoupling. However, MIMcap solutions typically require or utilize a relatively large IC device area. Often times, IC devices do not have the requisite available area to provide enough decoupling capacitance utilizing MIMcap solutions.

In some IC devices, there are various empty areas or non-utilized areas between the metal lines. To meet predetermined uniform metal density requirement(s) for chemical mechanical polish (CMP) control, or the like, the empty areas may include dummy metal shapes or features. For example, as depicted in FIG. 1, a prior art IC device 10 includes a wiring level 11 that includes dummy metal feature(s) 20 between conductive wiring line 12 and conductive wiring line 14. The dummy metal feature(s) 20 are metal features that are not connected to another wire feature above or below.

### SUMMARY

In an embodiment of the invention, a method of fabricating an integrated circuit (IC) device is presented. The method includes forming a pair of wiring lines within a Back End (BE) wiring dielectric layer. The method also includes forming an interleaved comb capacitor within the BE wiring dielectric layer between the pair of wiring lines. The interleaved comb capacitor includes a first conductive comb separated from a second conductive comb by the BE wiring dielectric layer.

In another embodiment of the present invention, an integrated circuit (IC) device is presented. The IC device includes a pair of wiring lines within a Back End (BE) wiring dielectric layer. The IC device further includes an interleaved comb capacitor within the BE wiring dielectric layer between the pair of wiring lines. The interleaved comb capacitor includes a first conductive comb separated from a second conductive comb by the BE wiring dielectric layer.

In another embodiment of the present invention, a method of fabricating an integrated circuit (IC) device is presented. The method includes forming a pair of wiring lines within a Back End (BE) wiring dielectric layer. The method further includes forming a first capacitor plate within the BE wiring dielectric layer between the pair of wiring lines. The first capacitor plate includes a plurality of perforations therethrough. The method further includes forming a capping layer upon the BE wiring dielectric layer, upon the pair of wiring lines, and upon the perforated capacitor plate. The method further includes forming a second capacitor plate upon the capping layer.

These and other embodiments, features, aspects, and advantages will become better understood with reference to the following description, appended claims, and accompanying drawings.

### BRIEF DESCRIPTION OF THE DRAWINGS

So that the manner in which the above recited features of the present invention are attained and can be understood in detail, a more particular description of the invention, briefly summarized above, may be had by referencing the description of the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 depicts a normal view of a prior art IC device wiring level that includes dummy feature(s) between wiring lines.

FIG. 2 depicts a normal view of an IC device wiring level that includes a capacitor between wiring lines, according to exemplary embodiments.

FIG. 3-FIG. 6 depicts a cross-section cut-away view of an IC device during respective fabrication stages, according to exemplary embodiments.

FIG. 7-FIG. 11 depict cross-section cut-away views of an IC device that includes a capacitor between wiring lines within the same wiring level, according to exemplary embodiments.

FIG. 12-FIG. 14 depict a normal view of an IC device wiring level that includes a capacitor plate between wiring lines, according to exemplary embodiments.

FIG. 15-FIG. 19 depicts a cross-section cut-away view of an IC device during respective fabrication stages, according to exemplary embodiments.

FIG. 20 depicts a cross-section cut-away view of an IC device that includes a capacitor plate between wiring lines within the same wiring level, according to exemplary embodiments.

FIG. 21 depicts a method of fabrication and utilization of an IC device that includes a capacitor between wiring lines within the same wiring level, according to exemplary embodiments.

FIG. 22 depicts a method of fabrication and utilization of an IC device that includes a capacitor plate between wiring lines within the same wiring level, according to exemplary embodiments.

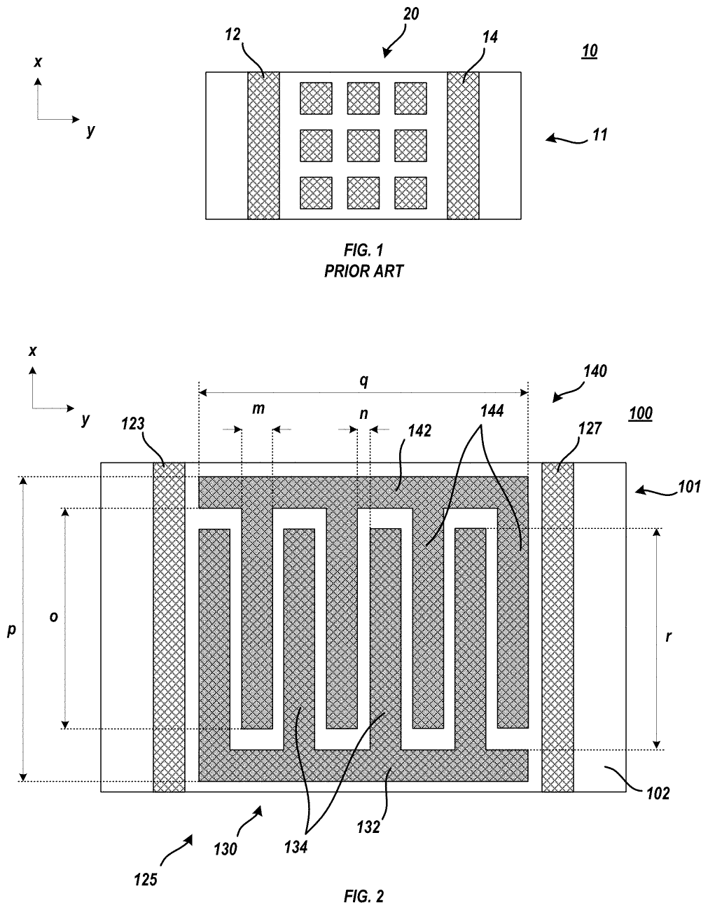

The drawings are not necessarily to scale and are intended to depict exemplary embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. These exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

Fabrication processes are disclosed where capacitor is assembled and coupled with IC device. Such embodiments allow for IC device designers to decouple components, functionality, regions, or the like, such as between logic components and memory components of the IC device.

FIG. 2 depicts a normal view of an IC device wiring level 101 of an IC device 100 that includes a capacitor 125 between wiring line 123 and wiring line 127, according to exemplary embodiments. Such embodiments relate to an IC device 100, such as a wafer, processor, application specific integrated circuit (ASIC), field programmable gate array (FPGA), or the like that includes a capacitor 125 between wiring line 123 and wiring line 127 within the same wiring level 101.

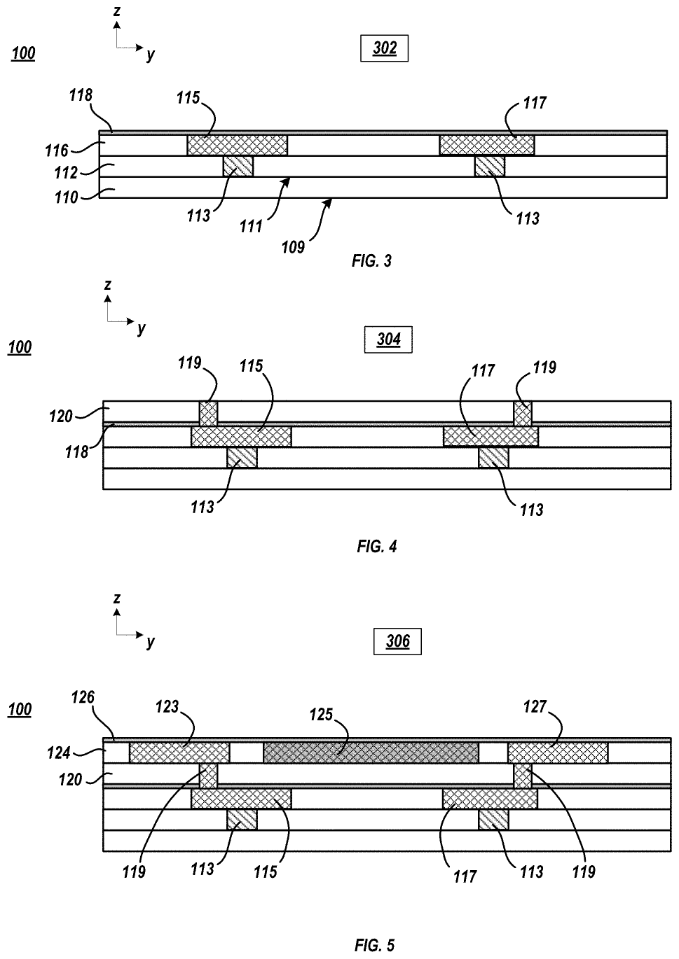

Wiring level 101 is apart of IC device 100 Back End (BE) interconnect stack. The BE interconnect stack may include a dielectric 102 that includes metal circuit traces formed there within or thereupon. Metal traces may also be referred to as wiring, wiring lines, or the like. The BE interconnect stack is made up metallization or wiring layers or levels, such as from metal-1 (M1) up to metal-n (Mn) such as M11, but not limited to M11. Wiring level 101 may formed upon a Front End (FE) metallization layer of the IC device 100 or upon a relatively lower wiring level. For example, wiring level 101 may be formed upon FE metallization layer 112, depicted in FIG. 3 or may be formed upon BE inter layer dielectric (ILD) layer 120, depicted in FIG. 5. In other words, wiring level 101 may be any one of the M1 to Mn metallization or wiring levels of IC device 100.

Wiring level 101 includes a wiring line 123 and a wiring line 127 formed upon or within a dielectric layer 102, as is known in the art. According to embodiments, wiring level 101 also includes capacitor 125 between wiring line 123 and wiring line 127. Wiring line 123, 127 are metal or otherwise conductive circuit traces that are configured as a conduit for electrical current. Wiring line 123 may include a portion that is parallel with a portion of wiring line 127. For example, as depicted, a section of wiring level 101 includes a portion of wiring line 123 that is parallel with a portion of wiring line 127 in the normal view x-y plane.

Capacitor 125 is a single plane (i.e., formed in a single x-y plane) interleaved comb capacitor. Capacitor 125 includes a first conductive comb 130 interleaved with a second conductive comb 140. Conductive comb 130 includes base 132 from which multiple spaced prongs 134 extend therefrom. Similarly, conductive comb 140 includes base 142 from which multiple spaced prongs 144 extend therefrom. Conductive comb 130 is arranged with respect to conductive comb 140 such that prongs 134 are interleaved with prongs 144. For example, along a y-axis through the prongs of capacitor 125, a prong 134 iteratively alternates with a prong 144. Capacitor 125 may be located between wiring line 123 and wiring line 127 such that base 132 and base 142 is perpendicular to wiring lines 123, 127, as depicted. In this implementation, the prongs 134, 144 may be parallel to wiring lines 123, 127. Alternatively, capacitor 125 may be located between wiring line 123 and wiring line 127 such that base 132 and base 142 is parallel to wiring lines 123, 127. In this implementation, the prongs 134, 144 may be perpendicular to wiring lines 123, 127.

Prongs 134 and prongs 144 are generally separated by a dielectric (e.g. dielectric 102, or the like). A non-ground potential may be applied to conductive comb 130 and a ground potential may be applied to conductive comb 140, or vice versa. Thus, the charge of one conductive comb exerts a force on the charge carriers within the other conductive comb, attracting opposite polarity charge and repelling like polarity charges, thus an opposite polarity charge will be induced on the surface of the other conductive comb. The conductive combs thus form a capacitor that holds opposite charges on the conductive comb facing surfaces and an electric field is formed between the prongs 134 and prongs 144.

In embodiments, dimensions “m,” “n,” “o,” “p,” “q,” “r,” or the like, may be adjusted or tuned to achieve desired capacitance characteristics, to achieve desired uniform metal density requirement(s), or the like. Further, the number of instances of prongs 134, 144 may be adjusted or tuned to achieve desired capacitance characteristics, to achieve desired uniform metal density requirement(s), or the like. For example, the number of instances of prongs 134, 144 and the dimensions “m,” “n,” “o,” “p,” “q,” “r,” or the like may be adjusted to meet a predetermined metal density requirement, such as a CMP uniformity requirement for Cu metallization.

FIG. 3 depicts a cross-section cut-away view of IC device 100 during a fabrication stage 302, according to exemplary embodiments. At fabrication stage 302, a BE wiring dielectric layer 116 is formed upon a FE metallization layer 112, wiring lines 115, 117 are formed within the BE wiring dielectric layer 116, and a capping layer 118 is formed upon the wiring BE dielectric layer 116 and upon the wiring lines 115, 117.

A semiconductor substrate 110 includes an active surface 111 and a backside surface 109 as well as FE metallization layer 112. In embodiments, the semiconductor substrate 110 is a semiconductor material such as but not limited to silicon (Si), silicon germanium (SiGe), germanium (Ge), or III-V compound semiconductors. The semiconductor substrate 110 can be monocrystalline, epitaxial crystalline, or polycrystalline. In embodiments, the semiconductor substrate 110 is a semiconductor heterostructure such as but not limited to a silicon-on-insulator (SOI) substrate, or a multi-layered substrate comprising silicon, silicon germanium, germanium, III-V compound semiconductors, and any combinations thereof. Active devices are located at or below the active surface 112 and they refer to microelectronic components such as but not limited to gates, transistors, rectifiers, and isolation structures that form parts of integrated circuits. The active devices are coupled as functional circuits to an FE metallization trace 113 within the FE metallization layer 112, as is known in the art. FE metallization layer 112 may be an upper most or last FE layer of the IC device and may be dielectric layer, as is known in the art. The FE metallization trace 113 may be a conductive metal formed within the FE metallization layer 112, as is known in the art.

BE wiring dielectric layer 116 is formed upon FE metallization layer 112 and upon FE metallization trace 113 utilizing known techniques. For example, BE wiring dielectric layer 116 may be formed by known dielectric deposition techniques. Wiring lines 115, 117 may be formed within BE wiring dielectric layer 116 utilizing known techniques. For example, portions of BE wiring dielectric layer 116 may be removed by applying a mask (not shown) upon BE wiring dielectric layer 116, patterning the mask, removing the patterned portions of the mask to expose portions of the underlying BE wiring dielectric layer 116, etching away the exposed portions of BE wiring dielectric layer 116 to form wiring trenches within layer 116, etc. The materials of FE metallization layer 112 and BE wiring dielectric layer 116 may be chosen so the FE metallization layer 112 may further serve as an etch stop. A wiring trench may expose the upper surface of an FE metallization trace 113. Subsequently, wiring lines 115, 117 may be formed within the wiring trenches within BE wiring dielectric layer 116 and upon the exposed upper surface of the FE metallization trace 113, utilizing techniques known in the art. For example, a metal may be deposited, plated, or the like within the wiring trenches within BE wiring dielectric layer 116 and upon a FE metallization trace 113. An CMP polish, or the like, may planarize the upper surface of BE wiring dielectric layer 116 and wiring lines 115, 117. In some embodiments, BE wiring dielectric layer 116 may be the M1 metallization level within the BE interconnect stack of IC device 100.

Capping layer 118 is formed upon the wiring BE dielectric layer 116 and upon the wiring lines 115, 117. Capping layer 118 may be formed upon the wiring BE dielectric layer 116 and upon the wiring lines 115, 117 utilizing known techniques. For example, capping layer 118 may be a dielectric and may be formed by known dielectric deposition techniques.

FIG. 4 depicts a cross-section cut-away view of IC device 100 during a fabrication stage 304, according to exemplary embodiments. At fabrication stage 304, vertical interconnect access (VIA) interlayer dielectric (ILD) layer 120 is formed upon capping layer 118 and VIAs 119 are formed within the VIA ILD layer 120 upon wiring lines 115,117.

VIA ILD layer 120 is formed upon capping layer 118 utilizing known techniques. For example, VIA ILD layer 120 may be formed by known dielectric deposition techniques. VIAs 119 may be formed within VIA ILD layer 120 utilizing known techniques. For example, in a single damascene process, portions of VIA ILD layer 120 may be removed by applying a mask (not shown) upon VIA ILD layer 120, patterning the mask, removing the patterned portions of the mask to expose portions of the underlying VIA ILD layer 120, etching away the exposed portions of VIA ILD layer 120 to form VIA trenches within layer 120, 118, etc. A VIA trench may expose the upper surface of a wiring line 115,117. Subsequently, VIAs 119 may be formed within the VIA trenches and upon the upper surface of wiring line 115, 117, utilizing techniques known in the art. For example, a metal may be deposited, plated, or the like within the VIA trenches and upon a wiring line 115,117. An CMP polish, or the like, may planarize the upper surface of VIA ILD layer 120 and VIAs 119. Alternatively, VIA(s) and wiring lines can be formed at the same step utilizing known dual damascene process techniques.

FIG. 5 depicts a cross-section cut-away view of IC device 100 during a fabrication stage 306, according to exemplary embodiments. At fabrication stage 306, a BE wiring dielectric layer 124 is formed upon VIA ILD layer 120 and upon VIAs 119, wiring lines 123, 127 and capacitor 125 is formed within the BE wiring dielectric layer 124, and a capping layer 126 is formed upon the BE wiring dielectric layer 124, upon the wiring lines 123, 127, and upon the capacitor 125.

BE wiring dielectric layer 124 is formed upon VIA ILD layer 120 and upon VIAs 119 utilizing known techniques. For example, BE wiring dielectric layer 124 may be formed by known dielectric deposition techniques. Wiring lines 123, 127 and capacitor 125 may be formed within BE wiring dielectric layer 124 utilizing known techniques. For example, portions of BE wiring dielectric layer 124 may be removed by applying a mask (not shown) upon BE wiring dielectric layer 124, patterning the mask in the desired shape of the to be formed wiring and capacitor, removing the patterned portions of the mask to expose portions of the underlying BE wiring dielectric layer 124, etching away the exposed portions of BE wiring dielectric layer 124 to form wiring trenches and to form capacitor trenches within layer 124, respectively. For clarity, the wiring trenches and the capacitor trenches may be simultaneously formed. The materials of VIA ILD layer 120 and BE wiring dielectric layer 124 may be chosen so the VIA ILD layer 120 may further serve as an etch stop.

A wiring trench may expose the upper surface of VIA 119. Subsequently, a wiring line 123, 127 may be formed within a wiring trenches within BE wiring dielectric layer 124 and upon the exposed upper surface of a VIA 119, utilizing techniques known in the art. For example, a metal may be deposited, plated, or the like within the wiring trenches within BE wiring dielectric layer 124 and upon a VIA 119. Capacitor 125 may be formed within the capacitor trench(es) within BE wiring dielectric layer 124. For example, a metal may be deposited, plated, or the like within a capacitor trench associated with conductive comb 130 and within a capacitor trench associated with conductive comb 140. For clarity, wiring lines 123, 127 and the capacitor 125 may be simultaneously formed and be the same material. An CMP polish, or the like, may planarize the upper surface of BE wiring dielectric layer 124, wiring lines 123, 127, and capacitor 125. In some embodiments, BE wiring dielectric layer 124 may be the M2 metallization level within the BE interconnect stack of IC device 100. Therefore, it should be appreciated that wiring lines 123, 127 and capacitor 125 may be located within the same metallization level within the BE interconnect stack of IC device 100.

Capping layer 126 is formed upon the wiring BE dielectric layer 124, upon the wiring lines 123, 127, and upon the capacitor 125. Capping layer 126 may be formed upon the wiring BE dielectric layer 124, upon the wiring lines 123, 127, and upon the capacitor 125 utilizing known techniques. Capping layer 126 is a traditional capping layer within the BE interconnect stack that is formed upon and caps metallization or other circuit features along and is also formed upon and caps the BE wiring dielectric layer in which those metallization and/or circuit features are fabricated. For example, capping layer 126 may be a dielectric and may be formed by known dielectric deposition techniques.

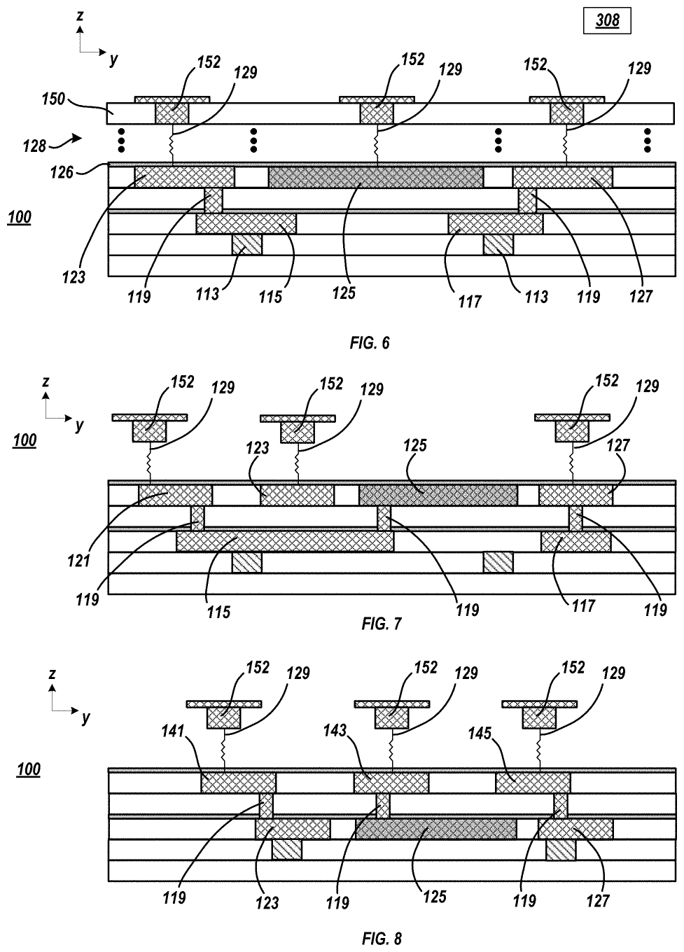

FIG. 6 depicts a cross-section cut-away view of IC device 100 during a fabrication stage 308, according to exemplary embodiments. At fabrication stage 308, additional BE interconnect stack level(s) 128 may be formed, a contact dielectric layer 150 is be formed, and contact pads 152 are formed within and/or upon the contact dielectric layer 150.

Additional BE interconnect stack level(s) 128 may be formed upon capping layer 126. For example, M3-Mn BE interconnect stack level(s) 128 may be formed utilizing known fabrication techniques. In some implementations, a VIA ILD layer may be formed upon a lower capping layer, VIAs may be formed within the VIA ILD layer and upon a respective lower wire, a BE wiring dielectric layer may be formed upon the VIA ILD layer and upon the VIAs therein, wiring may be formed within the BE wiring dielectric layer and upon a respective VIA, and a capping layer may be formed upon the BE wiring dielectric layer and upon the wiring formed therein. Such fabrication techniques may be repeated for each additional desired BE interconnect stack level(s) 128, as is known in the art.

Contact dielectric layer 150 is formed upon BE interconnect stack level(s) 128 or is formed upon e.g., capping layer 126 utilizing known techniques. For example, contact dielectric layer 150 may be formed by known dielectric deposition techniques. Contacts 152 may be formed within contact dielectric layer 150 utilizing known techniques. For example, portions of contact dielectric layer 150 may be removed by applying a mask (not shown) upon contact dielectric layer 150, patterning the mask in the desired grid or array of the to be formed contacts 152, removing the patterned portions of the mask to expose portions of the underlying contact dielectric layer 150, etching away the exposed portions of contact dielectric layer 150 to expose an upper surface of a BE interconnect stack 129, to expose an upper surface of wiring 123, 125, and/or to expose an upper surface of capacitor 125.

A contact trench may expose the upper surface of a BE interconnect stack 129 or the upper surface of wiring line 123, as appropriate. A contact trench may expose the upper surface of a BE interconnect stack 129 or the upper surface of wiring line 123, as appropriate. Subsequently, a contact 152 may be formed within a contact trenches and upon the exposed upper surface of a BE interconnect stack 129 or the upper surface of wiring line 123. Similarly, a contact 152 may be formed within a contact trench and upon the exposed upper surface of capacitor 125. For example, a metal may be deposited, plated, or the like within the contact trenches. A contact pad may be formed upon contact 152 and upon contact dielectric layer 150 utilizing techniques known in the art. Contacts 152 are generally the electrically conductive interconnects of the IC device 100 that are configured to electrically connect with respective contacts of a different and higher level device such as an IC device carrier, motherboard, or the like.

It should be appreciated that a BE interconnect stack may be fabricated to form an electrically conductive pathway from a contact 152 to a FE metallization trace 113 through wiring 123, 115, or the like. Similarly, it should be appreciated that a BE interconnect stack may be fabricated to form an electrically conductive pathway from a contact 152 to a FE metallization trace 113 through wiring 127, 117, or the like.

Likewise, it should be appreciated that a BE interconnect stack may be fabricated to form an electrically conductive pathway from a contact 152 to conductive comb 130 (e.g., to base 132, to one or more prongs 134) of capacitor 125 and that a BE interconnect stack may be fabricated to form an electrically conductive pathway from a contact 152 to conductive comb 140 (to base 142, to one or more prongs 144) of capacitor 125. For example, the BE interconnect stack 129 depicted in the y-z plane cross section of FIG. 6 may be fabricated to form an electrically conductive pathway from a contact 152 to conductive comb 130 of capacitor 125 and another BE interconnect stack 129, in a different y-z plane cross section into or out of the page to that depicted in FIG. 6, may be fabricated to form an electrically conductive pathway from a contact 152 to conductive comb 140 of capacitor 125. The higher level system to which IC device 100 may be connected may force or otherwise apply ground or non-ground potential, as appropriate, to such BE interconnect stacks to force distinct charges upon conductive comb 130 and conductive comb 140.

Therefore, it should be further appreciated that wiring 123 and 127 is a part of a respective BE interconnect stack or electrically conductive pathway to one or more respective microelectronic devices that are in electrical communication with respective FE metallization traces 113. In embodiments, the BE interconnect stack or electrically conductive pathway from capacitor 125 to contact 152 may terminate with capacitor 125. In other words, the BE interconnect stack or electrically conductive pathway may end at capacitor 125 such that capacitor 125 is not electrically connected to a FE metallization trace 113.

Electrically conductive materials may be selected to obtain useful capacitor 125 embodiments. In embodiments, combs 130, 140 are made from a metal. In embodiments, the wiring 123, 127 and combs 130, 140 may be a copper composition. In embodiments, the wiring 123, 127 and combs 130, 140 may be a titanium nitride (TixNy) composition where x and y may be chosen to make up either stoichiometric or non-stoichiometric ratios. In embodiments, the wiring 123, 127 and combs 130, 140 may be titanium. In embodiments, the wiring 123, 127 and combs 130, 140 may be tantalum. In embodiments, the wiring 123, 127 and combs 130, 140 may be a tantalum nitride (TaxNy) composition where x and y may be chosen to make up either stoichiometric or non-stoichiometric ratios.

In embodiments, combs 130, 140 and wiring lines 123, 127 have a thickness is in a range from 20 to 200 nanometer (nm). Dielectric materials may be selected to obtain useful capacitor 125 and wiring line embodiments. In embodiments, a high-k dielectric (k>6) is used for appropriate enumerated dielectric layer(s). In embodiments, an oxide is used for appropriate enumerated dielectric layer(s). In embodiments, silicon dioxide (SiO2) is used for appropriate enumerated dielectric layer(s). In embodiments, hafnium oxide (HfxOy) where x and y may be chosen to make up either stoichiometric or non-stoichiometric ratios is used for appropriate enumerated dielectric layer(s). In embodiments, aluminum oxide (AlxOy) where x and y may be chosen to make up either stoichiometric or non-stoichiometric ratios is used for appropriate enumerated dielectric layer(s). In embodiments, lead zirconate titanate (PZT) is used for appropriate enumerated dielectric layer(s). In embodiments, barium strontium titanate (BST) is used for appropriate enumerated dielectric layer(s). In embodiments, a low K dielectric material (k<6) is used for appropriate enumerated dielectric layers.

In embodiments, a mixture of low K and high K dielectric materials may be utilized, such as a low K dielectric material between metal lines and a high K dielectric material between capacitive elements. In embodiments, a mixture of oxides is used for appropriate enumerated dielectric layer(s) and a different oxide is used for a neighboring dielectric layer(s). In embodiments, a given dielectric layer is a mixture of two or more oxides. In an example embodiment, a dielectric layer is a hafnium oxide and a neighboring dielectric is an aluminum oxide. It may now be understood by these examples that a dielectric layer may be of a first composition such as hafnium oxide and another dielectric layer may be of a second composition such as aluminum oxide. One dielectric layer may be of “the same” as the other dielectric layer such as identical chemistries. One dielectric layer may be “different” from the other dielectric layer such as the same qualitative chemistries but of different stoichiometries. One dielectric layer may be “different” from the other dielectric layer such as the different qualitative chemistries such as a halfnium oxide in one and an aluminum oxide in the other. One dielectric layer may be “different” from the other dielectric layer such as the different qualitative chemistries such as a halfnium oxide in one and a mixture of an aluminum oxide and halfnium oxide in the other. One dielectric layer may be “different” from the other layer such as the different qualitative chemistries such as an aluminum oxide in one and a mixture of an aluminum oxide and halfnium oxide in the other. By these embodiments it should be understood that other dielectric materials may be mixed and matched for example where different capacitances are useful between the combs 130, 140.

In embodiments, the VIAs may have a VIA liner adhesion layer that assists in making a useful bond between the VIAs and adjacent structures. Formation of the VIA liner adhesion layer may be done by a chemical vapor deposition of a liner material such as titanium or tungsten, as is known in the art. In embodiments, the adhesion layer is titanium. In embodiments, the adhesion layer is titanium tungsten (TiW). In embodiments, the adhesion layer is tantalum. In embodiments, the adhesion layer may be a bilayer. For example, the adhesion layer may be a bilayer of Tantalum Nitride and Tantalum deposited by chemical or physical vapor deposition. Thickness of the adhesion layer may be useful in a range from 50 to 500 Angstrom (Å) according to embodiments.

In embodiments, the VIAs 119 and/or contacts 152 are copper elements or another metal. Electrical coupling of the contacts 152 to external electrical features may be accomplished in embodiments by electrical bumps that are disposed on contacts 152 utilizing techniques known in the art. The electrical bumps may be solder and part of a controlled-collapse chip connection (C4) that can be attached to conductive traces of an IC device carrier, or the like. In embodiments, the electrical bumps have a diameter in a range from 50 to 100 μm.

In embodiments, the capacitor 125 is used as a decoupling capacitor. The decoupling capacitor can be formed between power (+V) and ground (gnd) to decouple an integrated circuit associated with a microelectronic device in or upon the semiconductor substrate 110 without changing or affecting an existing circuit layout in the silicon. In embodiments, the capacitor 125 is used as a noise filter. In embodiments, the capacitor 125 is used as a sensor.

FIG. 7 depicts a cross-section cut-away view of IC device 100 that includes capacitor 125 between wiring lines 123, 127 within the same wiring level, according to exemplary embodiments. In the depicted embodiment, capacitor 125 is connected to wiring in a lower wring level. The wiring and capacitor features depicted may be fabricated utilizing those techniques described above.

A BE interconnect stack 129 may be fabricated to form an electrically conductive pathway from a contact 152 to wiring 123. Similarly, a BE interconnect stack 129 may be fabricated to form an electrically conductive pathway from a contact 152 to wiring 127. Such interconnects stacks 129 that are associated with wiring lines 123, 127 further include a connection to a FE metallization trace 113, as is described herein. For example, wiring 127 may be connected to a FE metallization trace 113 in a different y-z plane that that depicted in FIG. 7, wiring 117 may be connected to a FE metallization trace 113, or the like.

A BE interconnect stack may be fabricated to form an electrically conductive pathway from a contact 152 to conductive comb 130 (e.g., to base 132, to one or more prongs 134) of capacitor 125 through a wiring line 115 that is in a lower wiring level than capacitor 125. Similarly, a BE interconnect stack may be fabricated to form an electrically conductive pathway from a contact 152 to conductive comb 140 (to base 142, to one or more prongs 144) of capacitor 125 through a wiring line 115 that is in a lower wiring level than capacitor 125. For example, the BE interconnect stack depicted in the y-z plane cross section of FIG. 7 may be fabricated to form an electrically conductive pathway from a contact 152 to conductive comb 130 of capacitor 125 through wiring 115 and another BE interconnect stack, in a different y-z plane cross section into or out of the page to that depicted in FIG. 7, may be fabricated to form an electrically conductive pathway from a contact 152 to conductive comb 140 of capacitor 125 through wiring in a lower wiring level than capacitor 125.

As described, wiring 123 and 127 is a part of a respective BE interconnect stack or electrically conductive pathway to one or more respective microelectronic devices that are in electrical communication with respective FE metallization traces 113. In some embodiments, the capacitor 125 is not directly electrically connected to a FE metallization trace 113 but may be indirectly connected to a FE metallization trace through its power (e.g. VDD) connection or its ground connection. For example, the wiring that provides ground to the capacitor 125 is also connected to a FE metallization trace 113. The higher level system to which IC device 100 may be connected may force or otherwise apply ground or non-ground potential, as appropriate, to such BE interconnect stacks to force distinct charges upon conductive comb 130 and conductive comb 140.

FIG. 8 depicts a cross-section cut-away view of IC device 100 that includes capacitor 125 between wiring lines 123, 127 within the same wiring level, according to exemplary embodiments. In the depicted embodiment, capacitor 125 is connected to wiring in a higher wring level. The wiring and capacitor features depicted may be fabricated utilizing those techniques described above.

A BE interconnect stack 129 may be fabricated to form an electrically conductive pathway from a contact 152 to wiring 123. Similarly, a BE interconnect stack 129 may be fabricated to form an electrically conductive pathway from a contact 152 to wiring 127. Such interconnects stacks 129 that are associated with wiring lines 123, 127 further include a connection to a FE metallization trace 113, as is described herein.

A BE interconnect stack may be fabricated to form an electrically conductive pathway from a contact 152 to conductive comb 130 (e.g., to base 132, to one or more prongs 134) of capacitor 125 through a wiring line 143 that is in a higher wiring level than capacitor 125. Similarly, a BE interconnect stack may be fabricated to form an electrically conductive pathway from a contact 152 to conductive comb 140 (to base 142, to one or more prongs 144) of capacitor 125 through a wiring line 143 that is in a higher wiring level than capacitor 125. For example, the BE interconnect stack depicted in the y-z plane cross section of FIG. 8 may be fabricated to form an electrically conductive pathway from a contact 152 to conductive comb 130 of capacitor 125 through wiring 143 and another BE interconnect stack, in a different y-z plane cross section into or out of the page to that depicted in FIG. 8, may be fabricated to form an electrically conductive pathway from a contact 152 to conductive comb 140 of capacitor 125 through wiring in a higher wiring level than capacitor 125.

As described, wiring 123 and 127 is a part of a respective BE interconnect stack or electrically conductive pathway to one or more respective microelectronic devices that are in electrical communication with respective FE metallization traces 113. In some embodiments, the capacitor 125 is not directly electrically connected to a FE metallization trace 113 but may be indirectly connected to a FE metallization trace through its power (e.g. VDD) connection or its ground connection. For example, the wiring that provides ground to the capacitor 125 is also connected to a FE metallization trace 113. The higher level system to which IC device 100 may be connected may force or otherwise apply ground or non-ground potential, as appropriate, to such BE interconnect stacks to force distinct charges upon conductive comb 130 and conductive comb 140.

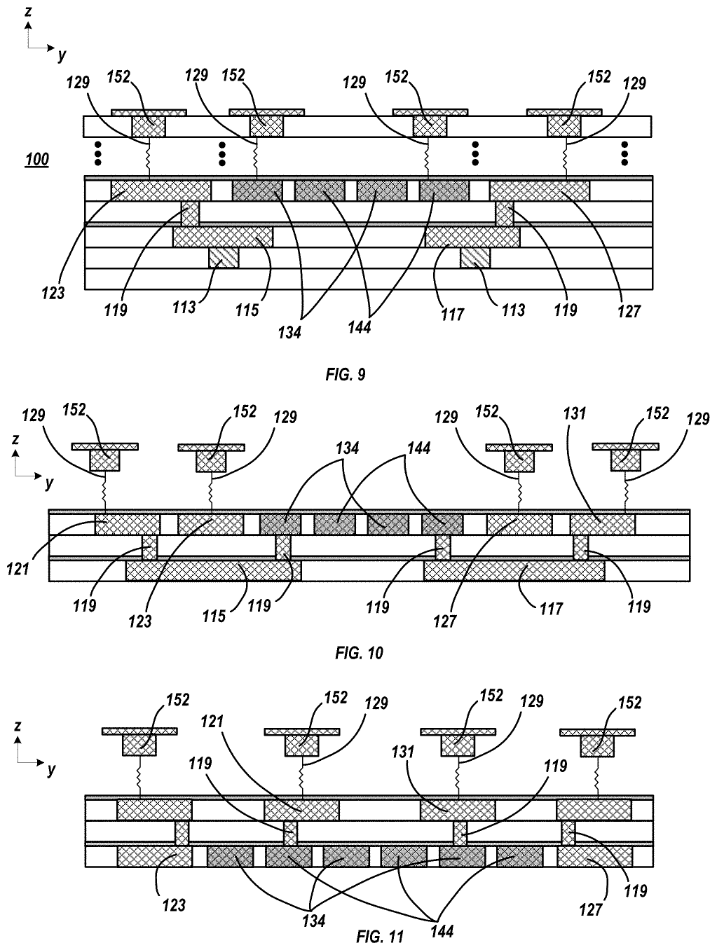

FIG. 9 depicts a cross-section cut-away view of IC device 100 that includes capacitor 125 between wiring lines 123, 127 within the same wiring level, according to exemplary embodiments. In the depicted embodiment, a prong 134 is connected to a BE interconnect stack 129 while a prong 144 is connected to a different BE interconnect stack 129. The wiring and capacitor features depicted may be fabricated utilizing those techniques described above.

A BE interconnect stack 129 may be fabricated to form an electrically conductive pathway from a contact 152 to a FE metallization trace 113 through wiring 123. Similarly, a BE interconnect stack 129 may be fabricated to form an electrically conductive pathway from a contact 152 to a FE metallization trace 113 through wiring 127.

A BE interconnect stack 129 may be fabricated to form an electrically conductive pathway from a contact 152 to one or more prongs 134 of capacitor 125. Similarly, a BE interconnect stack 129 may be fabricated to form an electrically conductive pathway from a contact 152 to one or more prongs 144 of capacitor 125.

As described, wiring 123 and 127 is a part of a respective BE interconnect stack or electrically conductive pathway to one or more respective microelectronic devices that are in electrical communication with respective FE metallization traces 113. In some embodiments, the capacitor 125 is not directly electrically connected to a FE metallization trace 113 but may be indirectly connected to a FE metallization trace through its power (e.g. VDD) connection or its ground connection. For example, the wiring that provides ground to the capacitor 125 is also connected to a FE metallization trace 113. The higher level system to which IC device 100 may be connected may force or otherwise apply ground or non-ground potential, as appropriate, to such BE interconnect stacks 129 to force distinct charges upon conductive prongs 134 and prongs 144.

FIG. 10 depicts a cross-section cut-away view of IC device 100 that includes capacitor 125 between wiring lines 123, 127 within the same wiring level, according to exemplary embodiments. In the depicted embodiment, capacitor 125 is connected to wiring in a lower wring level. The wiring and capacitor features depicted may be fabricated utilizing those techniques described above.

A BE interconnect stack 129 may be fabricated to form an electrically conductive pathway from a contact 152 to wiring 123. Similarly, a BE interconnect stack 129 may be fabricated to form an electrically conductive pathway from a contact 152 to wiring 127. Such interconnects stacks 129 that are associated with wiring lines 123, 127 further include a connection to a FE metallization trace 113, as is described herein. For example, wiring 123, 127 may be connected to respective FE metallization traces 113 in one or more different y-z plane that that depicted in FIG. 7.

A BE interconnect stack may be fabricated to form an electrically conductive pathway from a contact 152 to one or more prongs 134 of capacitor 125 through a wiring line 115 that is in a lower wiring level than capacitor 125. Similarly, a BE interconnect stack may be fabricated to form an electrically conductive pathway from a contact 152 to one or more prongs 144 of capacitor 125 through a wiring line 117 that is in a lower wiring level than capacitor 125.

As described, wiring 123 and 127 is a part of a respective BE interconnect stack or electrically conductive pathway to one or more respective microelectronic devices that are in electrical communication with respective FE metallization traces 113. The higher level system to which IC device 100 may be connected may force or otherwise apply ground or non-ground potential, as appropriate, to such BE interconnect stacks to force distinct charges upon prongs 134 and prongs 144.

FIG. 11 depicts a cross-section cut-away view of IC device 100 that includes capacitor 125 between wiring lines 123, 127 within the same wiring level, according to exemplary embodiments. In the depicted embodiment, capacitor 125 is connected to wiring in a higher wring level. The wiring and capacitor features depicted may be fabricated utilizing those techniques described above.

A BE interconnect stack may be fabricated to form an electrically conductive pathway from a contact 152 to wiring 123. Similarly, a BE interconnect stack may be fabricated to form an electrically conductive pathway from a contact 152 to wiring 127. Such interconnects stacks that are associated with wiring lines 123, 127 further include a connection to a FE metallization trace 113, as is described herein.

A BE interconnect stack may be fabricated to form an electrically conductive pathway from a contact 152 to one or more prongs 134 of capacitor 125 through a wiring line 121 that is in a higher wiring level than capacitor 125. Similarly, a BE interconnect stack may be fabricated to form an electrically conductive pathway from a contact 152 to one or more prongs 144 of capacitor 125 through a wiring line 131 that is in a higher wiring level than capacitor 125.

As described, wiring 123 and 127 is a part of a respective BE interconnect stack or electrically conductive pathway to one or more respective microelectronic devices that are in electrical communication with respective FE metallization traces 113. In some embodiments, the capacitor 125 is not directly electrically connected to a FE metallization trace 113 but may be indirectly connected to a FE metallization trace through its power (e.g. VDD) connection or its ground connection. For example, the wiring that provides ground to the capacitor 125 is also connected to a FE metallization trace 113. The higher level system to which IC device 100 may be connected may force or otherwise apply ground or non-ground potential, as appropriate, to such BE interconnect stacks to force distinct charges upon conductive comb 130 and conductive comb 140.

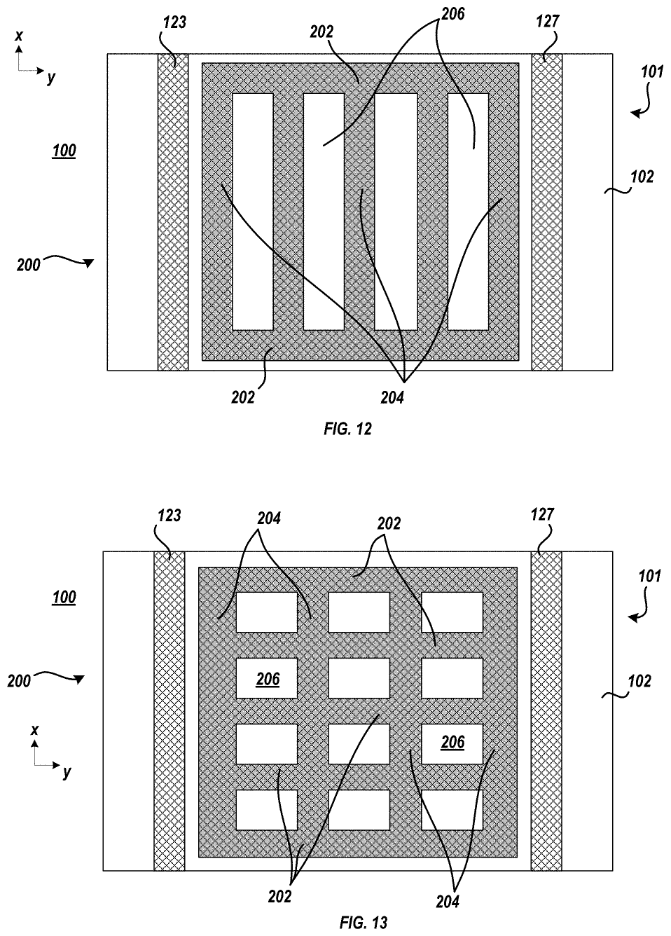

FIG. 12 depicts a normal view of an IC device 100 that includes a BE wiring level 101 that includes a capacitor plate 200 between wiring lines 123, 127. Embodiments of invention that include capacitor plate 200 generally relate to an IC device 100, such as a wafer, processor, ASIC, FPGA, or the like that includes a capacitor made from capacitor plate 200 between wiring lines 123, 127 within the same wiring level 101 and a capacitor plate 220, shown e.g., in FIG. 16, separated by a traditional BE metallization layer capping layer.

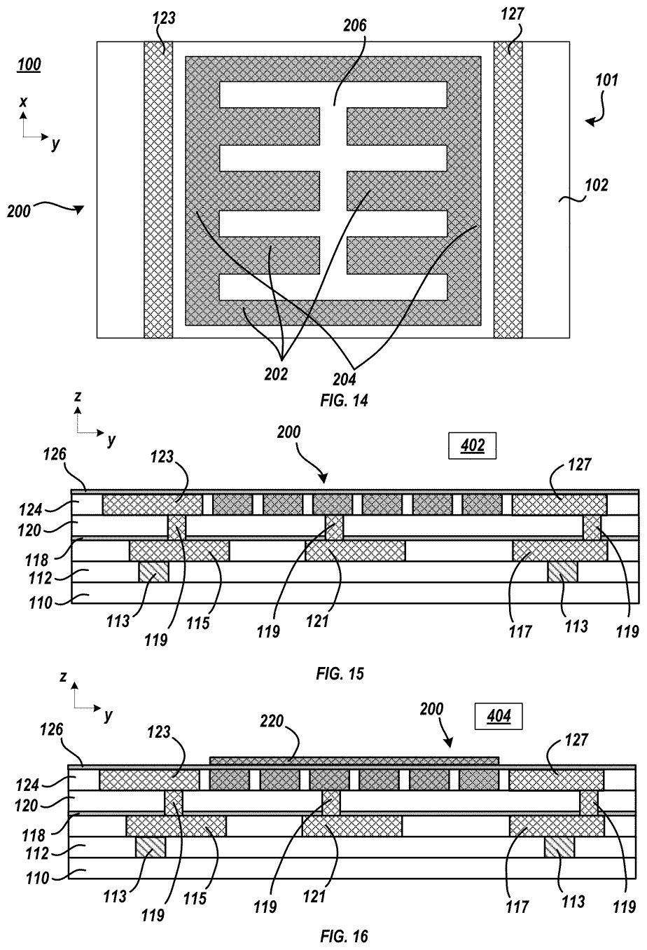

Capacitor plate 200 is a perforated electrically conductive plate in that there are one or more openings 206 internal or otherwise located within the perimeter of the capacitor plate 200. The openings 206 extend entirely through the capacitor plate 200 so as to forms holes, openings, perforations etc., through the capacitor plate. For example, capacitor plate 200 may be a mesh or the like. As depicted in FIG. 12, openings 206 may be oriented generally parallel with wiring lines 123, 127. As depicted in FIG. 13, openings 206 may be oriented generally orthogonal with wiring lines 123, 127. As depicted in FIG. 14, opening(s) 206 may include portions that are oriented generally orthogonal with wiring lines 123, 127 and portions that are orientated generally parallel with wiring lines 123, 127. The shape of opening(s) 206 depicted are merely illustrative of the contemplated structures and should not limit the scope of capacitor plate 200 unless otherwise claimed herein.

Capacitor plate 200 may include orthogonal portions 202 and parallel portions 204. Orthogonal portions 202 are generally orthogonal or perpendicular to wiring lines 123, 127 and parallel portions 204 are generally parallel to wiring lines 123, 127. In embodiments, the normal x-y plane area of openings 206 and/or the locations of openings 206 within the perimeter of capacitor plate 200 may be chosen, may be adjusted, or tuned to achieve desired capacitance characteristics, to achieve desired uniform metal density requirement(s), or the like. For example, if greater capacitance is desired, the area of the one or more openings 206 may be reduced until a maximum uniform metal density requirement is achieved.

FIG. 15 depicts a cross-section cut-away view of IC device 100 during respective fabrication stage 402, according to exemplary embodiments. At fabrication stage 402, wiring lines 123, 127 and capacitor plate 200 is formed within BE wiring dielectric layer 124 and a capping layer 126 is formed upon the wiring BE dielectric layer 124, upon the wiring lines 123, 127, and upon the capacitor plate 200. In embodiments, fabrication stages 302 and 304 may occur prior to fabrication stage 204.

BE wiring dielectric layer 124 is formed upon VIA ILD layer 120 and upon VIAs 119 utilizing known techniques. For example, BE wiring dielectric layer 124 may be formed by known dielectric deposition techniques. Wiring lines 123, 127 and capacitor plate 200 may be formed within BE wiring dielectric layer 124 utilizing known techniques. For example, portions of BE wiring dielectric layer 124 may be removed by applying a mask (not shown) upon BE wiring dielectric layer 124, patterning the mask in the desired shape of the to be formed wiring and capacitor plate, removing the patterned portions of the mask to expose portions of the underlying BE wiring dielectric layer 124, etching away the exposed portions of BE wiring dielectric layer 124 to form wiring trenches and to form capacitor plate trenches within layer 124, respectively. For clarity, the wiring trenches and the plate capacitor trenches may be simultaneously formed. The materials of VIA ILD layer 120 and BE wiring dielectric layer 124 may be chosen so the VIA ILD layer 120 may further serve as an etch stop.

A wiring trench and/or a capacitor trench may expose the upper surface of VIA 119. Subsequently, a wiring line 123, 127 may be formed within a wiring trench within BE wiring dielectric layer 124 and upon the exposed upper surface of a VIA 119 utilizing techniques known in the art. For example, a metal may be deposited, plated, or the like within the wiring trenches within BE wiring dielectric layer 124 and upon a VIA 119. Capacitor plate 200 may be formed within the capacitor plate trench within BE wiring dielectric layer 124 and upon an exposed upper surface of a VIA 119. For example, a metal may be deposited, plated, or the like within the capacitor plate trench and upon the VIA 119. For clarity, wiring lines 123, 127 and the capacitor plate 200 may be simultaneously formed and be the same material. An CMP polish, or the like, may planarize the upper surface of BE wiring dielectric layer 124, wiring lines 123, 127, and capacitor plate 200. In some embodiments, BE wiring dielectric layer 124 may be the M2 metallization level within the BE interconnect stack of IC device 100. Therefore, it should be appreciated that wiring lines 123, 127 and capacitor plate 200 may be located within the same metallization level within the BE interconnect stack of IC device 100.

Capping layer 126 is formed upon the wiring BE dielectric layer 124, upon the wiring lines 123, 127, and upon the capacitor plate 200. Capping layer 126 may be formed upon the wiring BE dielectric layer 124, upon the wiring lines 123, 127, and upon the capacitor plate 200 utilizing known techniques. For example, capping layer 126 may be a dielectric and may be formed by known dielectric deposition techniques. Capping layer 126 is a traditional capping layer within the BE interconnect stack that is formed upon and caps metallization or other circuit features along and is also formed upon and caps the BE wiring dielectric layer in which those metallization and/or circuit features are fabricated.

FIG. 16 depicts a cross-section cut-away view of IC device 100 during respective fabrication stage 404, according to exemplary embodiments. At fabrication stage 404, capacitor plate 220 is formed upon capping layer 126.

Capacitor plate 220 is an electrically conductive plate. In one embodiment, capacitor plate 220 is not perforated like capacitor plate 200 (i.e., there are no openings internal to the x-y plane perimeter of capacitor plate 220), as depicted. In alternative embodiments, capacitor plate 220 may be a perforated electrically conductive plate in that there are one or more openings internal or otherwise located within the perimeter of the capacitor plate 220. In some implementations, capacitor plate 220 may be a second instance of the same perforated electrically conductive plate as that of capacitor plate 200. In some embodiments, to minimize z-axis height of IC device 100, capacitor plate 220 may have a smaller thickness relative to capacitor plate 200, as depicted. In some embodiments, the perimeter or sidewalls of capacitor plate 220 are coplanar and/or coincident with the perimeter or sidewalls of capacitor plate 200, as depicted.

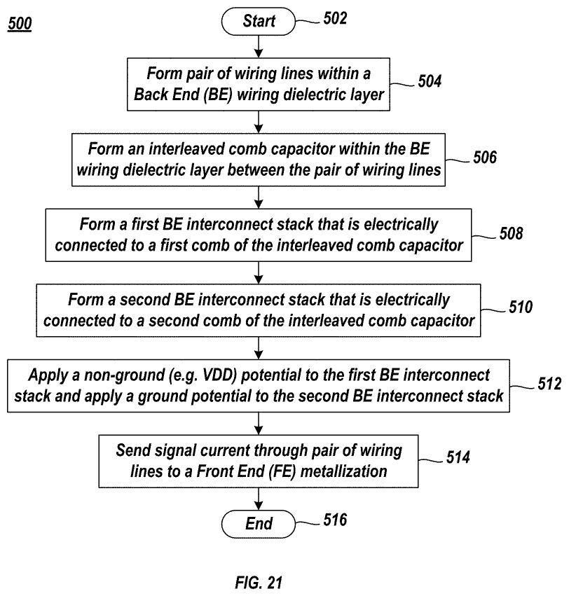

In some embodiments, as is exemplarily depicted in FIG. 20, capacitor plate 220 may extend beyond one or more capacitor plate 200 sidewall(s). In these implementations, VIA 119 may be formed upon and contact the portion(s) of capacitor plate 220 that extends beyond the footprint of capacitor plate 200. Due to the relative thinness of capacitor plate 220, it may be beneficial to form VIA 119 in such extension region(s) so as to limit the likelihood of etching through capping layer 126 during VIA 119 formation which may lead to a short between capacitor plate 220 and capacitor plate 200.

Capacitor plate 220 may be formed upon the capping layer 126 utilizing known techniques. For example, a mask may be applied upon capping layer 126, the mask may be patterned in the desired shape of the to be formed capacitor plate 220, the patterned portions of the mask may be removed to expose portions of the underlying capping layer 126 and to form capacitor plate trench(es) within the mask. The materials of mask and capping 126 may be chosen so the capping layer 126 may serve as an etch stop for the etchant that removes portions of the mask. Subsequently, capacitor plate 220 may be formed within capacitor plate trench(es) within the mask, utilizing techniques known in the art. For example, a metal may be deposited, plated, or the like within capacitor plate trench(es).

Therefore, it should be understood that capacitor plate 200 is generally separated by a traditional capping layer from capacitor plate 220. A non-ground potential may be applied to capacitor plate 200 and a ground potential may be applied to capacitor plate 220, or vice versa. Thus, the charge of capacitor plate 220 exerts a force on the charge carriers within the other capacitor plate 220, attracting opposite polarity charge and repelling like polarity charges, thus an opposite polarity charge will be induced on the surface of the capacitor plate 220, or vice versa. The capacitor plates 200, 220 thus may form a capacitor that holds opposite charges on the capacitor plate facing surfaces and an electric field is formed across the traditional capping layer.

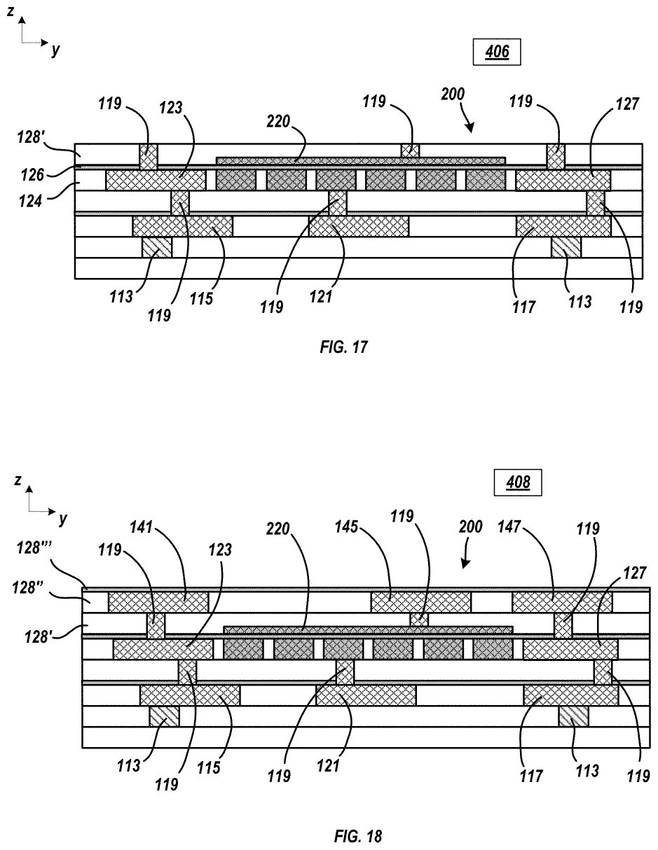

FIG. 17 depicts a cross-section cut-away view of IC device 100 during a fabrication stage 406, according to exemplary embodiments. At fabrication stage 406, VIA ILD layer 128′ is formed upon capping layer 126 and formed upon capacitor plate 220 and VIAs 119 are formed within the VIA ILD layer 128′ upon wiring lines 123, 127 and upon capacitor plate 220.

VIA ILD layer 128′ is formed upon capping layer 126 and upon capacitor plate 220 utilizing known techniques. For example, VIA ILD layer 128′ may be formed by known dielectric deposition techniques. VIAs 119 may be formed within VIA ILD layer 128′ utilizing known techniques. For example, portions of VIA ILD layer 128′ may be removed by applying a mask (not shown) upon VIA ILD layer 128′, patterning the mask, removing the patterned portions of the mask to expose portions of the underlying VIA ILD layer 128′, etching away the exposed portions of VIA ILD layer 128′ to form VIA trenches within layer 128′, 126, etc. A VIA trench may expose a portion or the upper surface of a wiring line 123, 127 and an portion of the upper surface of capacitor plate 220. Subsequently, VIAs 119 may be formed within the VIA trenches upon the exposed portion of wiring line 123, 127 and upon the exposed portion of capacitor plate 220 utilizing known techniques in the art. For example, a metal may be deposited, plated, or the like within the VIA trenches upon wiring line 123, 127 and upon capacitor plate 220. An CMP polish, or the like, may planarize the upper surface of VIA ILD layer 128′ and VIAs 119.

FIG. 18 depicts a cross-section cut-away view of IC device 100 during respective fabrication stage 408, according to exemplary embodiments. At fabrication stage 408, wiring lines 141, 145, and 147 are formed within BE wiring dielectric layer 128″ and a capping layer 128′″ is formed upon the wiring BE dielectric layer 128″, upon the wiring lines 141, 145, and 147. These wiring lines and wiring dielectric layers may be fabricated utilizing known single damascene or known dual damascene fabrication techniques.

BE wiring dielectric layer 128″ is formed upon VIA ILD layer 128′ and upon VIAs 119 utilizing known techniques. For example, BE wiring dielectric layer 128″ may be formed by known dielectric deposition techniques. Wiring lines 141, 145, 147 may be formed within BE wiring dielectric layer 128″ utilizing known techniques. For example, portions of BE wiring dielectric layer 128″ may be removed by applying a mask (not shown) upon BE wiring dielectric layer 128″, patterning the mask in the desired shape of the to be formed wiring, removing the patterned portions of the mask to expose portions of the underlying BE wiring dielectric layer 128″, etching away the exposed portions of BE wiring dielectric layer 128″ to form wiring trenches within layer 128″. The materials of VIA ILD layer 128′ and BE wiring dielectric layer 128″ may be chosen so the VIA ILD layer 128′ may further serve as an etch stop.

A wiring trench may expose the upper surface of VIA 119. Subsequently, a wiring line 141, 145, 147 may be formed within a respective wiring trench within BE wiring dielectric layer 128″ and upon the exposed upper surface of a VIA 119, utilizing techniques known in the art. For example, a metal may be deposited, plated, or the like within the wiring trenches within BE wiring dielectric layer 128″ and upon a VIA 119. An CMP polish, or the like, may planarize the upper surface of BE wiring dielectric layer 128″ and wiring lines 141, 145, 147. In some embodiments, BE wiring dielectric layer 128″ may be the M3 metallization level within the BE interconnect stack of IC device 100.

Capping layer 128′″ may be formed upon the wiring BE dielectric layer 128″ and upon the wiring lines 141, 145, and 147 utilizing known techniques. For example, capping layer 128′″ may be a dielectric and may be formed by known dielectric deposition techniques.

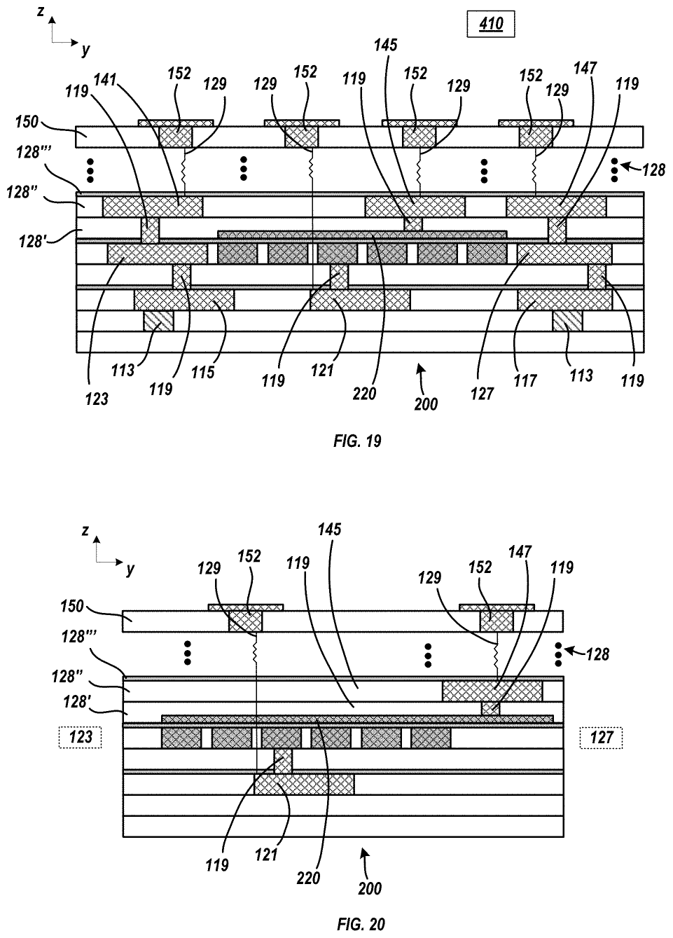

FIG. 19 depicts a cross-section cut-away view of IC device 100 during a fabrication stage 410, according to exemplary embodiments. At fabrication stage 410, additional BE interconnect stack level(s) 128 may be formed, a contact dielectric layer 150 is be formed, and contact pads 152 are formed within and/or upon the contact dielectric layer 150.

Additional BE interconnect stack level(s) 128 may be formed upon capping layer 128′″. For example, M4-Mn BE interconnect stack level(s) 128 may be formed utilizing known fabrication techniques. In some implementations, a VIA ILD layer may be formed upon a lower capping layer, VIAs may be formed within the VIA ILD layer and upon a respective lower wire, a BE wiring dielectric layer may be formed upon the VIA ILD layer and upon the VIAs therein, wiring may be formed within the BE wiring dielectric layer and upon a respective VIA, and a capping layer may be formed upon the BE wiring dielectric layer and upon the wiring formed therein. Such fabrication techniques may be repeated for each additional desired BE interconnect stack level(s) 128, utilizing known techniques in the art.

Contact dielectric layer 150 is formed upon BE interconnect stack level(s) 128′″ utilizing known techniques. For example, contact dielectric layer 150 may be formed by known dielectric deposition techniques. Contacts 152 may be formed within contact dielectric layer 150 utilizing known techniques. For example, portions of contact dielectric layer 150 may be removed by applying a mask (not shown) upon contact dielectric layer 150, patterning the mask in the desired grid or array of the to be formed contacts 152, removing the patterned portions of the mask to expose portions of the underlying contact dielectric layer 150, etching away the exposed portions of contact dielectric layer 150 to expose an upper surface of a BE interconnect stack 129, to expose an upper surface of wiring, to expose an upper surface of capacitor plate 220, or the like.

A contact trench may expose the upper surface of a BE interconnect stack 129 or the upper surface of wiring line, as appropriate. Subsequently, a contact 152 may be formed within a contact trenches and upon the exposed upper surface. Similarly, a contact 152 may be formed within a contact trench and upon the exposed upper surface of capacitor 125. For example, a metal may be deposited, plated, or the like within the contact trenches. A contact pad may be formed upon contact 152 and upon contact dielectric layer 150, utilizing techniques known in the art. Contacts 152 are generally the electrically conductive interconnects of the IC device 100 that are configured to electrically connect with respective contacts of a different and higher level device such as an IC device carrier, motherboard, or the like.

It should be appreciated that a BE interconnect stack may be fabricated to form an electrically conductive pathway from a contact 152 to a FE metallization trace 113 through wiring 123, 115, or the like. Similarly, it should be appreciated that a BE interconnect stack may be fabricated to form an electrically conductive pathway from a contact 152 to a FE metallization trace 113 through wiring 127, 117, or the like.

Likewise, it should be appreciated that a BE interconnect stack may be fabricated to form an electrically conductive pathway from a contact 152 to capacitor plate 200. For example, a BE interconnect stack 129 may be fabricated to form an electrically conductive pathway from a contact 152 to wiring 121 and from wiring 121 to capacitor plate 200. Similar, it should be appreciated that a BE interconnect stack may be fabricated to form an electrically conductive pathway from a contact 152 to capacitor plate 220. For example, a BE interconnect stack 129 may be fabricated to form an electrically conductive pathway from a contact 152 to wiring 145 and from wiring 14 to capacitor plate 220. The higher level system to which IC device 100 may be connected may force or otherwise apply ground or non-ground potential, as appropriate, to such BE interconnect stacks to force distinct charges upon capacitor plate 200 and capacitor plate 220.

Therefore, it should be further appreciated that wiring 123 and 127 is a part of a respective BE interconnect stack or electrically conductive pathway to one or more respective microelectronic devices that are in electrical communication with respective FE metallization traces 113. In embodiments, the BE interconnect stacks or electrically conductive pathways associated with capacitor plate 200 and plate 220 may end at capacitor plate 200 and plate 220 such that the capacitor made up by capacitor plate 200 and capacitor plate 220 is not electrically connected to a FE metallization trace 113 or associated microelectronic devices.

Electrically conductive materials may be selected to obtain useful capacitor embodiments. In embodiments, the wiring 123, 127, capacitor plate 200, and/or capacitor plate 220 are made from a metal. In embodiments, the wiring 123, 127, capacitor plate 200, and/or capacitor plate 220 may be a copper composition. In embodiments, the wiring 123, 127, capacitor plate 200, and/or capacitor plate 220 may be a titanium nitride (TixNy) composition where x and y may be chosen to make up either stoichiometric or non-stoichiometric ratios. In embodiments, the wiring 123, 127, capacitor plate 200, and/or capacitor plate 220 may be titanium. In embodiments, the wiring 123, 127, capacitor plate 200, and/or capacitor plate 220 may be tantalum. In embodiments, the wiring 123, 127, capacitor plate 200, and/or capacitor plate 220 may be a tantalum nitride (TaxNy) composition where x and y may be chosen to make up either stoichiometric or non-stoichiometric ratios.

In embodiments, the wiring 123, 127, capacitor plate 200, and/or capacitor plate 220 have a thickness is in a range from 5 to 50 nanometer (nm). Dielectric materials may be selected to obtain useful capacitor plate and wiring line embodiments. In embodiments, a high-k dielectric (k>6) is used for appropriate enumerated dielectric layer(s). In embodiments, an oxide is used for appropriate enumerated dielectric layer(s). In embodiments, silicon dioxide (SiO2) is used for appropriate enumerated dielectric layer(s). In embodiments, hafnium oxide (HfxOy) where x and y may be chosen to make up either stoichiometric or non-stoichiometric ratios is used for appropriate enumerated dielectric layer(s). In embodiments, aluminum oxide (AlxOy) where x and y may be chosen to make up either stoichiometric or non-stoichiometric ratios is used for appropriate enumerated dielectric layer(s). In embodiments, lead zirconate titanate (PZT) is used for appropriate enumerated dielectric layer(s). In embodiments, barium strontium titanate (BST) is used for appropriate enumerated dielectric layer(s). In embodiments, capping layer 126 may be Aluminum Nitride (AlN), Silicon Nitride (SiN), Carbon-doped Silicon Nitride (SiCN), or the like

In embodiments, a mixture of oxides is used for appropriate enumerated dielectric layer(s) and a different oxide is used for is used for a neighboring dielectric layer(s). In embodiments, a given dielectric layer is a mixture of two or more oxides. In an example embodiment, a dielectric layer is a hafnium oxide and a neighboring dielectric is an aluminum oxide. It may now be understood by these examples that a dielectric layer may be of a first composition such as hafnium oxide and another dielectric layer may be of a second composition such as aluminum oxide. One dielectric layer may be of “the same” as the other dielectric layer such as identical chemistries. One dielectric layer may be “different” from the other dielectric layer such as the same qualitative chemistries but of different stoichiometries. One dielectric layer may be “different” from the other dielectric layer such as the different qualitative chemistries such as a halfnium oxide in one and an aluminum oxide in the other. One dielectric layer may be “different” from the other dielectric layer such as the different qualitative chemistries such as a halfnium oxide in one and a mixture of an aluminum oxide and halfnium oxide in the other. One dielectric layer may be “different” from the other layer such as the different qualitative chemistries such as an aluminum oxide in one and a mixture of an aluminum oxide and halfnium oxide in the other. By these embodiments it should be understood that other dielectric materials may be mixed and matched for example where different capacitances are useful between capacitor plate 200 and capacitor plate 220.

In embodiments, the capacitor made by capacitor plate 200 and capacitor plate 220 is used as a decoupling capacitor. The decoupling capacitor can be formed between power (+V) and ground (gnd) to decouple an integrated circuit associated with a microelectronic device in or upon the semiconductor substrate 110 without changing or affecting an existing circuit layout in the silicon. In embodiments, the capacitor made by capacitor plate 200 and capacitor plate 220 is used as a noise filter. In embodiments, the capacitor made by capacitor plate 200 and capacitor plate 220 is used as a sensor.

For clarity, a BE interconnect stack may include other depicted interconnect features. For example, as shown in FIG. 19, the BE interconnect stack that connects a contact 152 and a FE metallization trace 113 though wiring 115 includes BE interconnect stack 129, wiring 141, 123, 115, and various VIAs 119. On the other hand, a BE interconnect stack may include merely an enumerated BE interconnect stack 129. For example, as shown in FIG. 9, the BE interconnect stack that connects a contact 152 and prong 134, includes BE interconnect stack 129. It should be appreciated that in such embodiments, the BE interconnect stack 129 may include wiring, VIAs, or the like, as is known in the art, that form the BE interconnect stack 129.

In embodiments, the area(s) between wiring lines within the same wiring level that have no metal features therein and/or in the area(s) between wiring lines within the same wiring level that have dummy metal features there may be locations within an IC device in which the capacitive elements described herein may be utilized or otherwise fabricated. For example, in areas that previously include dummy metal features, the capacitive elements described herein may be fabricated in their place. As described such capacitive elements may serve the useful purpose of a decoupling capacitor, noise filter, sensor, or the like while also providing for the metal density requirement(s) previously satisfied by the dummy metal features.

FIG. 21 depicts method 500 of fabrication and utilization of IC device 100 that includes capacitor 125 between wiring lines 123, 127 within the same wiring level 101, according to exemplary embodiments. Method 500 begins at block 502 and continues with forming a pair of wiring lines within a BE wiring dielectric layer. For example, as described in fabrication stage 306, a BE wiring dielectric layer 124 is formed upon VIA ILD layer 120 and upon VIAs 119, wiring lines 123, 127 are formed within the BE wiring dielectric layer 124.

Method 500 may continue with forming an interleaved capacitor within the same BE wiring dielectric layer between the pair of wiring lines (block 507). For example, as described in fabrication stage 306, capacitor 125 may be formed within the BE wiring dielectric layer 124 between wiring lines 123, 127. For clarity capacitor 125 may be simultaneously formed as wiring lines 123, 127 and may be the same material. Alternatively, capacitor 125 may be formed prior to or subsequent to the wiring lines 123, 127 and may be a different material relative to wiring lines 123, 127.

Method 500 may continue with forming a BE interconnect stack that is connected to a first comb of the interleaved capacitor (block 508). For example, as described in fabrication stage 308, a BE interconnect stack 129 is formed within the BE layers and is connected to e.g., prong 130. Method 500 may continue with forming a BE interconnect stack that is connected to a second comb of the interleaved capacitor (block 510). For example, as described in fabrication stage 308, a BE interconnect stack 129 is formed within the BE layers and is connected to e.g., prong 140.

Method 500 may continue with applying a non-ground (e.g., VDD, power, etc.) potential to the first interconnect stack and applying a ground potential to the second interconnect stack, or vice versa (block 512). For example, a system level contact may apply the non-ground potential to contact 152 to prong 130 through the associated interconnect stack 129 and another system level contact may apply the ground potential to contact 152 to prong 140 through the associated interconnect stack 129. Method 500 may continue with sending a signal current through the pair of wiring lines to a respective FE metallization (block 514). For example, a system may send the signal current through a system level contact to a contact 152 through the BE interconnect stack to wiring line 123 and to the associated FE metallization 113. Similarly, the system may send another signal current through another system level contact to a contact 152 through the BE interconnect stack to wiring line 127 and to the associated FE metallization 113. Method 500 may end at block 516.

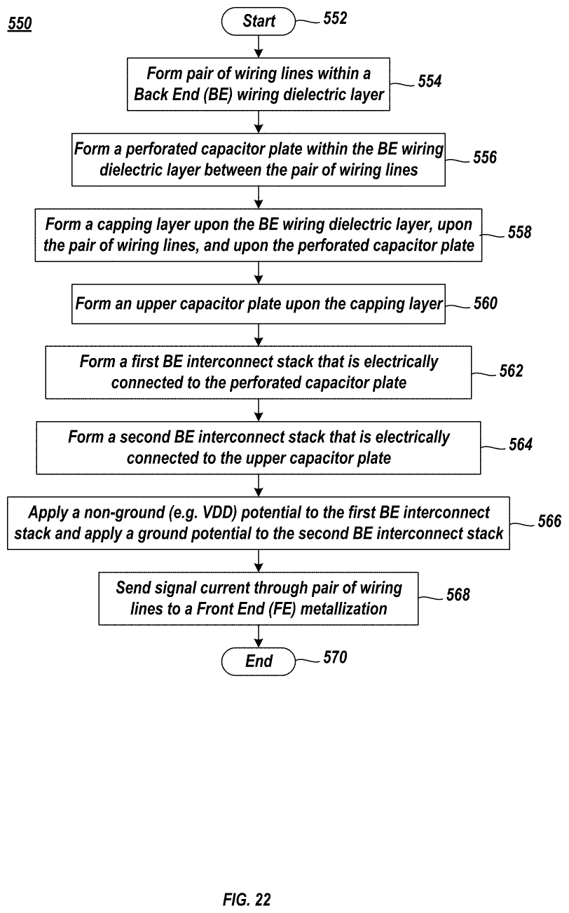

FIG. 22 depicts method 550 of fabrication and utilization of IC device 100 that includes a capacitor plate 200 between wiring lines 123, 127 within the same wiring level 101, according to exemplary embodiments. Method 550 begins at block 552 and continues with forming a pair of wiring lines within a BE wiring dielectric layer (block 554). For example, as described in fabrication stage 402, wiring lines 123, 127 are formed within BE wiring dielectric layer 124.

Method 550 continues with forming a perforated capacitor plate within the same BE wiring dielectric between the pair of wiring lines (block 556). For example, as described in fabrication stage 402, capacitor plate 200 is formed within BE wiring dielectric layer 124. For clarity capacitor plate 200 may be simultaneously formed as wiring lines 123, 127 and may be the same material. Alternatively, capacitor plate 200 may be formed prior to or subsequent to the wiring lines 123, 127 and may be a different material relative to wiring lines 123, 127.

Method 550 may continue with forming a capping layer upon the BE wiring dielectric layer, upon the pair of wiring lines, and upon the perforated capacitor plate (block 558). For example, as described in fabrication stage 402, capping layer 126 is formed upon the wiring BE dielectric layer 124, upon the wiring lines 123, 127, and upon the capacitor plate 200.

Method 550 may continue with forming an upper capacitor plate upon the capping layer (block 560). For example, as described in fabrication stage 404, capacitor plate 220 is formed upon capping layer 126. Capacitor plate 220 may have sidewall(s) that are coplanar with sidewall(s) of the lower perforated capacitor plate 200, as is depicted in FIG. 19. Alternatively, plate 220 may have sidewall(s) in a plane beyond the plane of the sidewall(s) of the lower perforated capacitor plate 200, as is depicted in FIG. 20.

Method 550 may continue with forming a BE interconnect stack that is connected to the perforated capacitor plate (block 562). For example, a BE interconnect stack 129 is formed within the BE layers and is connected to capacitor plate 200 by way of wiring 121, as depicted in FIG. 19. Method 550 may continue with forming a BE interconnect stack that is connected to the upper capacitor plate (block 564). For example, a BE interconnect stack 129 is formed within the BE layers and is connected to capacitor plate 220 by way of wiring 145, as depicted in FIG. 19.

Method 550 may continue with applying a non-ground (e.g., VDD, power, etc.) potential to the perforated capacitor plate and applying a ground potential to the upper capacitor plate, or vice versa (block 566). For example, a system level contact may apply the non-ground potential to a contact 152 through BE interconnect stack 129 and to the perforated capacitor plate through wiring 121 and another system level contact may apply a ground potential to a contact 152 through BE interconnect stack 129 and to the upper capacitor plate through wiring 145 to the upper capacitor plate. Method 500 may continue with sending a signal current through the pair of wiring lines to a respective FE metallization (block 568). For example, a system may send the signal current through a system level contact to a contact 152 through the BE interconnect stack to wiring line 123 and to the associated FE metallization 113. Similarly, the system may send another signal current through another system level contact to a contact 152 through the BE interconnect stack to wiring line 127 and to the associated FE metallization 113. Method 550 may end at block 570.

The accompanying figures and this description depicted and described embodiments of the present invention, and features and components thereof. Those skilled in the art will appreciate that any particular nomenclature used in this description was merely for convenience, and thus the invention should not be limited by the specific process identified and/or implied by such nomenclature. Therefore, it is desired that the embodiments described herein be considered in all respects as illustrative, not restrictive, and that reference be made to the appended claims for determining the scope of the invention.

The exemplary methods and techniques described herein may be used in the fabrication of integrated circuit chips. The resulting integrated circuit chips can be distributed by the fabricator in raw wafer form (i.e., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). The chip is then integrated with other chips, discrete circuit elements and/or other signal processing devices as part of either (a) an intermediate product, such as a motherboard, or (b) an end product. The end product can be any product that includes integrated circuit chips, ranging from toys and other low-end applications to advanced computer products having numerous components, such as a display, a keyboard or other input device and/or a central processor, as non-limiting examples.

Unless described otherwise or in addition to that described herein, “forming” or the like, may include any now known or later developed techniques appropriate for the material to be fabricated, including, but not limited to: CVD, LPCVD, PECVD, semi-atmosphere CVD (SACVD), high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic level deposition (ALD), chemical oxidation, molecular beam epitaxy (MBE), plating, or evaporation.

References herein to terms such as “vertical”, “horizontal”, etc. are made by way of example, and not by way of limitation, to establish a frame of reference. The term “horizontal” as used herein is defined as a plane parallel to the conventional plane or surface of the substrate, regardless of the actual spatial orientation of the IC device. The term “vertical” refers to a direction perpendicular to the horizontal, as just defined. Terms, such as “on”, “above”, “below”, “side” (as in “sidewall”), “higher”, “lower”, “over”, “beneath” and “under”, are defined with respect to the horizontal plane. It is understood that various other frames of reference may be employed for describing the present invention without departing from the spirit and scope of the present invention.

1. A method of fabricating an integrated circuit (IC) device comprising:
forming a pair of wiring lines within a Back End (BE) wiring dielectric layer, the pair of wiring lines comprising a first wiring line electrically connected to a first Front End (FE) metallization trace by way of a first lower wiring line and a second wiring line electrically connected to a second FE metallization trace by way of a second lower wiring line;
forming an interleaved comb capacitor within the BE wiring dielectric layer between the pair of wiring lines, the interleaved comb capacitor comprising a first conductive comb separated from a second conductive comb by the BE wiring dielectric layer, wherein a top surface of the BE wiring dielectric layer, a top surface of the first conductive comb, a top surface of the second conductive comb, and a top surface of the pair of wiring lines are coplanar; wherein a sidewall of the first lower wiring line is between sidewalls of the interleaved comb capacitor; and wherein a sidewall of the second lower wiring line is between the sidewalls of the interleaved comb capacitor;
forming a contact dielectric layer upon the BE wiring dielectric layer, upon the pair of wiring lines, and upon the interleaved comb capacitor; and
forming an outer pair of contacts within the contact dielectric layer, the outer pair of contacts comprising: a first outer contact that provides a first signal current to the first FE metallization trace; and a second outer contact that provides a second signal current to the second FE metallization trace;
forming an inner pair of contacts within the contact dielectric layer between the outer pair of contacts, the inner pair of contacts comprising: a first inner contact that provides non-ground potential to the first conductive comb; and a second inner contact that provides ground potential to the second conductive comb; and
forming a C4 solder bump directly upon each of the outer pair of contacts and directly upon each of the inner pair of contacts, the C4 solder bumps configured to attach the IC device to a respective pad of an IC device carrier.

2. The method of claim 1, wherein the first conductive comb comprises a plurality of first spaced prongs and wherein the second conductive comb comprises a plurality of second spaced prongs.

3. The method of claim 2, wherein the plurality of first spaced prongs are interleaved with the plurality of second spaced prongs.

4. The method of claim 3, wherein the plurality of first spaced prongs are separated from the plurality of second spaced prongs by the BE wiring dielectric layer.

5. The method of claim 1, wherein the BE wiring dielectric layer is between a Front End (FE) metallization layer and the contact dielectric layer.

6.-20. (canceled)

21. A method of fabricating an integrated circuit (IC) device comprising:
forming a lower pair of wiring lines within a lower Back End (BE) wiring dielectric layer, the lower pair of wiring lines comprising a first lower wiring line electrically connected to a first Front End (FE) metallization trace and a second lower wiring line electrically connected to a second FE metallization trace;
forming an upper pair of wiring lines within an upper BE wiring dielectric layer, the upper pair of wiring lines comprising a first upper wiring line and a second upper wiring line;
forming an interleaved comb capacitor within the upper BE wiring dielectric layer between the upper pair of wiring lines, the interleaved comb capacitor comprising a first conductive comb separated from a second conductive comb by the upper BE wiring dielectric layer, wherein a top surface of the upper BE wiring dielectric layer, a top surface of the first conductive comb, a top surface of the second conductive comb, and a top surface of the upper pair of wiring lines are coplanar, wherein a sidewall of the first conductive comb is between sidewalls of the first lower wiring line; and wherein a sidewall of the second conductive comb is between the sidewalls of the second lower wiring line;
forming a first vertical interconnect access (VIA) that connects an upper surface of the first lower wiring line and a lower surface of the first conductive comb;
forming a second VIA that connects an upper surface of the second lower wiring line and a lower surface of the second conductive comb;
forming a contact dielectric layer upon the upper BE wiring dielectric layer, upon the upper pair of wiring lines, and upon the interleaved comb capacitor;
forming an outer pair of contacts within the contact dielectric layer, the outer pair of contacts comprising: a first outer contact that provides non-ground potential to the first lower wiring line, to the first FE metallization trace, and to the first conductive comb; and a second outer contact that provides ground potential to the second lower wiring line, to the second FE metallization trace and to the second conductive comb;
forming an inner pair of contacts within the contact dielectric layer between the outer pair of contacts, the inner pair of contacts comprising: a first inner contact that provides a first signal current to the first upper wiring line; and a second inner contact that provides a second signal current to the second upper wiring line; and
forming a C4 solder bump directly upon each of the outer pair of contacts and directly upon each of the inner pair of contacts, the C4 solder bumps configured to attach the IC device to a respective pad of an IC device carrier.

22. The method of claim 21, wherein the first conductive comb comprises a plurality of first spaced prongs, wherein the second conductive comb comprises a plurality of second spaced prongs, and wherein the plurality of first spaced prongs are interleaved with the plurality of second spaced prongs.

23.-32. (canceled)

33. The method of claim 22, wherein the plurality of first spaced prongs are separated from the plurality of second spaced prongs by the upper BE wiring dielectric layer.

34. The method of claim 21, wherein the upper BE wiring dielectric layer is between a Front End (FE) metallization layer and the contact dielectric layer.

35. A method of fabricating an integrated circuit (IC) device comprising:
forming a lower pair of wiring lines within a lower Back End (BE) wiring dielectric layer, the lower pair of wiring lines comprising a first lower wiring line electrically connected to a first Front End (FE) metallization trace and a second lower wiring line electrically connected to a second FE metallization trace;
forming an interleaved comb capacitor within the lower BE wiring dielectric layer between the lower pair of wiring lines, the interleaved comb capacitor comprising a first conductive comb separated from a second conductive comb by the lower BE wiring dielectric layer, wherein a top surface of the lower BE wiring dielectric layer, a top surface of the first conductive comb, a top surface of the second conductive comb, and a top surface of the lower pair of wiring lines are coplanar;
forming an upper pair of wiring lines within an upper BE wiring dielectric layer, the upper pair of wiring lines comprising a first upper wiring line and a second upper wiring line, wherein sidewalls of the first upper wiring line are between sidewalls of the interleaved comb capacitor; wherein sidewalls of the second upper wiring line are between sidewalls of the interleaved comb capacitor;
forming a first vertical interconnect access (VIA) that connects a lower surface of the first upper wiring line and an upper surface of the first conductive comb;
forming a second VIA that connects a lower surface of the second upper wiring line and a upper surface of the second conductive comb;
forming a contact dielectric layer upon the upper BE wiring dielectric layer and upon the upper pair of wiring lines;
forming an outer pair of contacts within the contact dielectric layer, the outer pair of contacts comprising: a first outer contact that provides a first signal current to the first lower wiring line; and a second outer contact that provides a second signal current to the second lower wiring line; and
forming an inner pair of contacts within the contact dielectric layer between the outer pair of contacts, the inner pair of contacts comprising: a first inner contact that provides non-ground potential to the first upper wiring line and to the first conductive comb; and a second inner contact that provides ground potential to the second upper wiring line and to the second conductive comb; and
forming a C4 solder bump directly upon each of the outer pair of contacts and directly upon each of the inner pair of contacts, the C4 solder bumps configured to attach the IC device to a respective pad of an IC device carrier.

36. The method of claim 35, wherein the first conductive comb comprises a plurality of first spaced prongs, wherein the second conductive comb comprises a plurality of second spaced prongs, and wherein the plurality of first spaced prongs are interleaved with the plurality of second spaced prongs.

37. The method of claim 36, wherein the plurality of first spaced prongs are separated from the plurality of second spaced prongs by the lower BE wiring dielectric layer.

38. The method of claim 35, wherein the lower BE wiring dielectric layer is between a Front End (FE) metallization layer and the contact dielectric layer.
